(19) United States
(12) Patent Application Publication
(10) Pub. No.: US 2015/0249205 A1
(43) Pub. Date: Sep. 3, 2015

(54) MAGNETIC ELEMENT, AND MAGNETIC HIGH FREQUENCY ELEMENT HAVING THE MAGNETIC ELEMENT

(71) Applicant: TDK CORPORATION, Tokyo (JP)

(72) Inventors: Takahiro SUWA, Tokyo (JP); Katsuyuki NAKADA, Tokyo (JP); Takumi AOKI, Tokyo (JP); Tomoyuki SASAKI, Tokyo (JP); Tetsuya SHIBATA, Tokyo (JP)

(21) Appl. No.: 14/630,121

(22) Filed: Feb. 24, 2015

(30) Foreign Application Priority Data
Feb. 28, 2014 (JP) 2014-037669
Feb. 10, 2015 (JP) 2015-024197

(51) Int. Cl. H01L 43/02; H01L 43/08

(52) U.S. Cl. CPC H01L 43/02; H01L 43/08

(57) ABSTRACT

A higher oscillation output is realized in a magnetic element utilizing high frequency characteristics of a magnetoresistive effect element. A magnetic element 1 includes a magnetoresistive effect film 10 including a magnetic pinned layer 14 and a magnetic free layer 12 with a non-magnetic spacer layer 13 interposed therebetween, and a pair of electrodes (lower electrode layer 11 and upper electrode layer 15) arranged with the magnetoresistive effect film 10 interposed therebetween in a stacking direction of the magnetoresistive effect film 10, wherein, given that a minimum value of an area of the magnetic free layer 12 in a section perpendicular to the stacking direction is denoted by Sf, and that a minimum value of an area of the magnetic pinned layer 14 in a section perpendicular to the stacking direction is denoted by Spm, relation of Sf>Spm is satisfied.

### BACKGROUND

The present invention relates to a magnetic element, and a magnetic high frequency element having the magnetic element.

Recently, attention has been focused on the field of spintronics utilizing charges and spins of electrons at the same time instead of the field of electronics employing charges of electrons. The spintronics greatly contributes to the industry in the form of a hard disk drive (HDD) and a magnetoresistive memory (MRAM) with quick development of magnetoresistive effect elements based on magnetoresistive effects that are represented by a giant magnetoresistive (GMR) effect and a tunneling magnetoresistive (TMR) effect.

Regarding a magnetoresistive effect element, it is known that, through transfer and transport of a spin of one ferromagnetic substance, energy (spin-transfer torque) to rotate a spin of the other ferromagnetic substance is generated. In trying to utilize the spin-transfer torque, when the spin-transfer torque and torque caused by an external magnetic field are brought into the condition of being close to each other, a spin oscillation and resonance phenomenon occurs. Utilizing such a phenomenon in industrial fields as devices for oscillation and detection, a mixer, a filter, etc. in the high frequency range has been proposed (Patent Reference 1).

An element (hereinafter referred to as a “magnetic element”) utilizing high frequency characteristics of the magnetoresistive effect element is regarded as being advantageous in points of size reduction, impedance matching with a transfer circuit, and variability of frequency characteristics in comparison with an element that is made of a semiconductor and that utilizes high frequency characteristics, and researches on a higher oscillation output of such a magnetic element are under progress with intention of realizing practical use. (Patent Reference 2)

### PRIOR ART REFERENCES

### Patent References

[Patent Reference 1] Japanese Unexamined Patent Application Publication No. 2006-295908

[Patent Reference 2] Japanese Unexamined Patent Application Publication No. 2011-181756

### SUMMARY

Patent Reference 1 discloses a magnetic element in which a magnetic free layer is processed into a microscopic shape at such a level that formation of a single magnetic domain is expectable. Patent Reference 1 states that macroscopically uniform precession of magnetization is developed in the magnetic free layer, whereby the purity of an oscillation signal is improved and a higher oscillation output is realized. With the disclosed method, however, since the magnetic free layer is processed into an area comparable to or smaller than that of a magnetic pinned layer, a current passes through an entire region of the magnetic free layer. In the magnetic element, application of an external magnetic field is essential to efficiently control the frequency and the output of oscillation. On that occasion, in an end portion of the magnetic free layer, magnetic flux is concentrated and a non-uniform magnetic field is generated, whereby the uniform precession of magnetization is impeded. This causes a problem that the purity of the oscillation signal degrades and the oscillation output reduces. Furthermore, when the magnetic element is processed, the dry etching method using inert gas, e.g., Ar, is carried out in the mainstream. With the dry etching method, however, denaturation and degradation due to impacts of atoms often generate in an end portion of an object to be processed. Thus, in the end portion of the magnetic free layer, the uniform precession of magnetization is further impeded, thereby escalating the problem that the purity of the oscillation signal degrades and the oscillation output reduces. In the present invention, the purity of the oscillation signal implies narrowness of a band of frequencies constituting the oscillation signal. When non-uniform precession of magnetization is developed in the end portion of the magnetic free layer or in an inner region thereof other than the end portion, signals having different frequencies are generated. Looking at the entirety of the magnetic element, therefore, a signal having a broadened band is generated and the oscillation output is reduced.

Patent Reference 1 further discloses a method for suppressing development of the non-uniform precession of magnetization by processing one or both of an upper electrode layer and a lower electrode layer into very small areas without processing the magnetic free layer and the magnetic pinned layer into not-so very small areas, and by obtaining a structure that a current passes only through a portion of the magnetic free layer, the portion corresponding to its region connected to the very small area of the upper electrode layer or the lower electrode layer, and that a current does not pass through the end portion of the magnetic free layer. This method is effective in a giant magnetoresistive (GMR) effect element in which a non-magnetic intermediate layer (non-magnetic spacer layer) is a conductor and overall resistance is small, but it is problematic in a tunneling magnetoresistive (TMR) effect element in which the non-magnetic intermediate layer is an insulator and overall resistance is large. More specifically, in the TMR effect element, a current having been temporarily confined in the upper electrode layer or the lower electrode layer is diffused into the magnetic free layer and the magnetic pinned layer to reduce a resistance value when the current tunnels through the non-magnetic intermediate layer. Therefore, the current passes through the entire region of the magnetic free layer including its end portion, thus causing the problem that the purity of the oscillation signal degrades due to development of the non-uniform precession of magnetization and the oscillation output reduces. When high frequency characteristics of the magnetoresistive effect element are utilized, a signal output is proportional to the second power of a magnetoresistive effect ratio (MR ratio). Thus, an improvement in the tunneling magnetoresistive (TMR) effect element capable of increasing the MR ratio is particularly demanded to increase the oscillation output.

Patent Reference 2 discloses a magnetic element in which the oscillation output is increased by controlling a perpendicular magnetic anisotropy of the magnetic free layer and the magnetic pinned layer, and by applying an external magnetic field in a direction perpendicular to a film surface. However, the disclosed magnetic element also accompanies with the problem that the purity of the oscillation signal degrades due to development of the non-uniform precession of magnetization, which is caused in the end portion of the magnetic free layer.

The present invention has been made in view of the above-mentioned problems, and an object of the present invention is to realize a higher oscillation output in a magnetic element that utilizes high frequency characteristics of a magnetoresistive effect element.

According to a first feature of the present invention aiming to achieve the above object, there is provided a magnetic element comprising a magnetoresistive effect film including a magnetic pinned layer and a magnetic free layer with a non-magnetic spacer layer interposed therebetween, and a pair of electrodes arranged with the magnetoresistive effect film interposed therebetween in a stacking direction of the magnetoresistive effect film, wherein, given that a minimum value of an area of the magnetic free layer in a section perpendicular to the stacking direction is denoted by Sf, and that a minimum value of an area of the magnetic pinned layer in a section perpendicular to the stacking direction is denoted by Spm, relation of Sf>Spm is satisfied.

According to the magnetic element of the present invention having the feature mentioned above, since the minimum value of the area of the magnetic free layer in the section perpendicular to the stacking direction is larger than the minimum value of the area of the magnetic pinned layer in the section perpendicular to the stacking direction, a current having been confined by the magnetic pinned layer passes through an end portion of the magnetic free layer in a smaller amount, and the amount of the current passing through an inner region of the magnetic free layer except for the end portion thereof is increased. A uniform external magnetic field is applied to the inner region of the magnetic free layer, and deterioration attributable to processing is not caused there. As a result, uniform precession of magnetization is generated in the magnetic free layer, whereby the purity of an oscillation signal is improved and a higher oscillation output is realized.

A non-magnetic insulating layer can be used as the non-magnetic spacer layer. In the present invention, however, the non-magnetic insulating layer is not limited to a layer used in a tunneling magnetoresistive effect (TMR) element and made of only a perfect insulator, and it involves a layer that is used in a nano-contact magnetoresistive (NCMR) effect element, and that contains, in an insulator, a conducting point formed by a conductor. In the nano-contact magnetoresistive (NCMR) effect element, because a resistance value is higher than that in the giant magnetoresistive (GMR) effect element, the following problem still remains. In a structure that one or both of the upper electrode layer and the lower electrode layer are processed just to have very small areas, a current having been temporarily confined by the upper electrode layer or the lower electrode layer is diffused in the magnetic free layer and the magnetic pinned layer. Therefore, the purity of the oscillation signal degrades due to development of the non-uniform precession of magnetization, and the oscillation output reduces. To cope with that problem, the effect of increasing the oscillation output is obtained with the present invention.

When an area of an interface at which the magnetic pinned layer and the non-magnetic spacer layer are in contact with each other is larger than the minimum value of the area of the magnetic pinned layer in the section perpendicular to the stacking direction, the current having been confined by a region of the magnetic pinned layer where the area of the magnetic pinned layer in the section perpendicular to the stacking direction is minimum is partly diffused again, and the effect of increasing the oscillation output with the present invention is weakened. In such a case, therefore, of a region of the magnetic pinned layer, the region being positioned closer to the non-magnetic spacer layer in the stacking direction than a position at which the area of the magnetic pinned layer in the section perpendicular to the stacking direction, a part positioned outside the region where the area of the magnetic pinned layer in the section perpendicular to the stacking direction is minimum is preferably thin. More preferably, the relevant part is so sufficiently thin as to lose electrical conductivity, or the relevant part is in a state where electrical conductivity is lost due to denaturation that is caused during the processing of the magnetic pinned layer.

A second feature of the magnetic element according to the present invention resides in that relation of Sf>2×Spm is satisfied.

According to the magnetic element of the present invention having the feature mentioned above, since the minimum value of the area of the magnetic free layer in the section perpendicular to the stacking direction is sufficiently larger than the minimum value of the area of the magnetic pinned layer in the section perpendicular to the stacking direction, the current having been confined by the magnetic pinned layer passes through the end portion of the magnetic free layer in an even smaller amount, and the amount of the current passing through the inner region of the magnetic free layer is further increased. A uniform external magnetic field is applied to the inner region of the magnetic free layer, and deterioration attributable to the processing is not caused there. As a result, uniform precession of magnetization is generated in the magnetic free layer, whereby the purity of an oscillation signal is improved and a higher oscillation output is realized.

A third feature of the magnetic element according to the present invention resides in that, given that when an area of the magnetic pinned layer in a section perpendicular to the stacking direction is denoted by Sp, a minimum distance between a section of the magnetic pinned layer perpendicular to the stacking direction, the section satisfying relation of Sf>2×Sp, and an interface at which the magnetic pinned layer and the non-magnetic spacer layer are in contact with each other is denoted by Lp, relation of Lp≦2 [nm] is satisfied.

According to the magnetic element of the present invention having the feature mentioned above, even when the area of the interface at which the magnetic pinned layer and the non-magnetic spacer layer are in contact with each other is larger than the minimum value of the area of the magnetic pinned layer in the section perpendicular to the stacking direction, the current having been confined through a region of the magnetic pinned layer, the region satisfying the relation of Sf>2×Sp, passes through the non-magnetic spacer layer and then flows into the magnetic free layer without being diffused again in the magnetic pinned layer up to a region corresponding to the area Sf. As a result, uniform precession of magnetization is generated in the magnetic free layer, whereby the purity of an oscillation signal is improved and a higher oscillation output is realized.

A fourth feature of the magnetic element according to the present invention resides in that, given that an area of an interface at which the magnetic pinned layer and the non-magnetic spacer layer are in contact with each other is denoted by Spn, relation of Sf>Spn is satisfied.

According to the magnetic element of the present invention having the feature mentioned above, since the current is confined by a portion of the magnetic pinned layer, the portion being in contact with the non-magnetic spacer layer, the effect of confining the current passing through the non-magnetic spacer layer and flowing into the magnetic free layer is increased. Thus, the current having been confined by the magnetic pinned layer passes through the end portion of the magnetic free layer in a smaller amount, and the amount of the current passing through the inner region of the magnetic free layer is increased. As a result, uniform precession of magnetization is generated in the magnetic free layer, whereby the purity of an oscillation signal is improved and a higher oscillation output is realized.

A fifth feature of the magnetic element according to the present invention resides in that relation of Sf>2×Spn is satisfied.

According to the magnetic element of the present invention having the feature mentioned above, since the area of the magnetic free layer in the section perpendicular to the stacking direction is sufficiently larger than the portion of the magnetic pinned layer where the magnetic pinned layer is in contact with the non-magnetic spacer layer and the current is confined. Thus, the current having been confined by the magnetic pinned layer passes through the end portion of the magnetic free layer in an even smaller amount, and the amount of the current passing through the inner region of the magnetic free layer is further increased. As a result, uniform precession of magnetization is generated in the magnetic free layer, whereby the purity of an oscillation signal is improved and a higher oscillation output is realized.

A sixth feature of the magnetic element according to the present invention resides in that relation of Spm<30000 [nm²] is satisfied.

According to the magnetic element of the present invention having the feature mentioned above, since the magnetic pinned layer is formed in a microscopic size, the inner region of the magnetic free layer where the current having been confined by the magnetic pinned layer passes is brought into a state of a single magnetic domain. As a result, macroscopically uniform precession of magnetization is developed in the magnetic free layer, whereby the purity of an oscillation signal is improved and a higher oscillation output is realized.

A magnetic high frequency element according to the present invention is featured in including the magnetic element described above, and a magnetic field supply mechanism that is installed near the free magnetic layer.

According to the magnetic high frequency element of the present invention having the feature mentioned above, when spin-transfer torque caused by an electron having been subjected to spin polarization and torque caused by an external magnetic field applied from the magnetic field supply mechanism are brought into the condition of being close to each other, great precession of magnetization is generated in the magnetic free layer, and a higher output of the oscillation signal is realized.

According to the present invention, the higher oscillation output can be realized in the magnetic element that utilizes the high frequency characteristics of the magnetoresistive effect element.

### BRIEF DESCRIPTION OF DRAWINGS

FIG. 1 is a plan view schematically illustrating a magnetic high frequency element of the present invention.

FIG. 2 is a sectional view illustrating a detailed multilayer structure of a magnetic element according to a first embodiment of the present invention.

FIG. 3 is a sectional view illustrating a detailed multilayer structure of a magnetic element according to a second embodiment of the present invention.

FIG. 4 is a sectional view illustrating a detailed multilayer structure of a magnetic element according to a third embodiment of the present invention.

FIG. 5 is a sectional view illustrating a detailed multilayer structure of a magnetic element according to a fourth embodiment of the present invention.

FIG. 6 is a sectional view illustrating a detailed multilayer structure of a magnetic element according to a fifth embodiment of the present invention.

FIG. 7 is a sectional view illustrating a detailed multilayer structure of a magnetic element according to a sixth embodiment of the present invention.

FIG. 8 is a sectional view illustrating a detailed multilayer structure of a magnetic element according to a seventh embodiment of the present invention.

FIG. 9 is a sectional view illustrating a detailed multilayer structure of a magnetic element according to an eighth embodiment of the present invention.

FIG. 10 is a sectional view illustrating a detailed multilayer structure of a magnetic element according to a ninth embodiment of the present invention.

FIG. 11 is a sectional view illustrating a detailed multilayer structure of a magnetic element according to a tenth embodiment of the present invention.

FIG. 12 is a block diagram of a device configuration to measure an oscillation output.

FIG. 13 is a graph representing relation between a frequency of an oscillation output and a power spectrum in a magnetic element of Example 1.

FIG. 14 is a sectional view illustrating a detailed multilayer structure of a magnetic element of Comparative Example 1.

FIG. 15 is a sectional view illustrating a detailed multilayer structure of a magnetic element of Comparative Example 5.

FIG. 16 is a graph representing relation between Sf/Spm and the oscillation output.

FIG. 17 is a graph representing relation between Sf/Spm and the oscillation output.

FIG. 18 is a graph representing relation between Lp and the oscillation output.

FIG. 19 is a graph representing relation between Lp and the oscillation output.

FIG. 20 is a graph representing relation between Spm and the oscillation output.

### DETAILED DESCRIPTION OF EMBODIMENTS

Preferred embodiments of the present invention will be described in detail below with reference to the drawings. The present invention is not limited by the matters described in the following embodiments. Furthermore, the following embodiments can be variously modified within the scope not departing from the gist of the present invention.

### First Embodiment

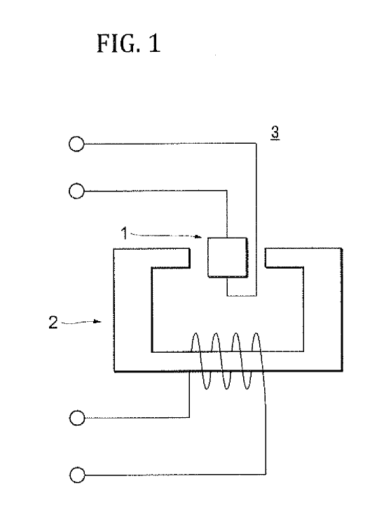

FIG. 1 is a plan view schematically illustrating a magnetic high frequency element 3 that utilizes high frequency characteristics of a magnetoresistive effect element, and that has the function of a device for oscillation and detection, a mixer, a filter, or the like in the high frequency range. The magnetic high frequency element 3 includes a magnetic element 1 connected to a high frequency circuit, and a magnetic field supply mechanism 2 that is disposed near a later-described magnetic free layer 12 in the magnetic element 1 with the intention of applying an external magnetic field to the magnetic free layer 12. The magnetic field supply mechanism 2 is a magnetic field supply mechanism of the electromagnet type capable of controlling the magnitude and the direction of an applied magnetic field depending on a voltage or a current.

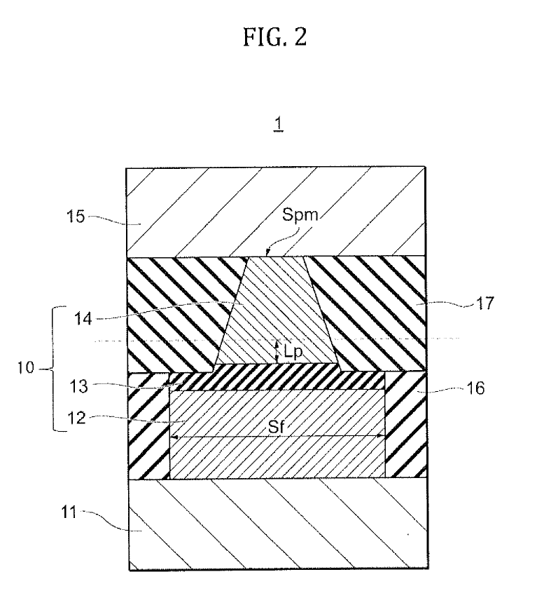

FIG. 2 is a sectional view illustrating a detailed multilayer structure of the magnetic element 1, illustrated in FIG. 1, according to the first embodiment of the present invention. In FIG. 2, some of components that are not important in understanding the present invention are omitted. In the magnetic element 1, a lower electrode layer 11, a magnetoresistive effect film 10, and an upper electrode layer 15 are successively disposed in the mentioned order. The magnetoresistive effect film 10 includes a magnetic free layer 12, a non-magnetic spacer layer 13, and a magnetic pinned layer 14. Thus, in the magnetic element 1, the lower electrode layer 11, the magnetic free layer 12, the non-magnetic spacer layer 13, the magnetic pinned layer 14, and the upper electrode layer 15 are successively disposed in the mentioned order. An insulator 16 and an insulator 17 are disposed on both sides of the above-mentioned layers in a direction parallel to film surfaces of the layers.

The lower electrode layer 11 serves as one of a pair of electrodes in combination with the upper electrode layer 15. In other words, the lower electrode layer 11 and the upper electrode layer 15 have the function as a pair of electrodes for supplying a current to flow through the magnetoresistive effect film 10 in a direction crossing respective surfaces of the layers constituting the magnetoresistive effect film 10, e.g., in a direction perpendicular to the respective surfaces of the layers constituting the magnetoresistive effect film 10 (i.e., in a stacking direction of the magnetoresistive effect film 10). In the following description, the “stacking direction of the magnetoresistive effect film 10” is simply denoted by the “stacking direction” in some cases.

The lower electrode layer 11 is constituted as a film made of Ta, Cu, Au, AuCu, or Ru, or a film made of two or more selected from among those materials, each film being formed by the sputtering method or the IBD method, for example. A film thickness of the lower electrode layer 11 is preferably about 0.05 μm to 5 μm. In the magnetic element 1, the shape of the electrode layer is important for the purpose of reducing the transmission loss. In the first embodiment of the present invention, the lower electrode layer 11 is specified into the coplanar waveguide (CPW) shape, when looking at the magnetic element 1 from above, by photoresist patterning or ion beam etching, for example.

The magnetic free layer 12, the non-magnetic spacer layer 13, and the magnetic pinned layer 14 are each formed by, e.g., a film-forming apparatus with sputtering. Film formation with sputtering is performed, for example, by employing argon sputtering gas and sputtering a target, which is made of a metal or an alloy, such that a film is formed on a substrate under ultrahigh vacuum.

A layer with the function of cutting off crystallinity of the lower electrode layer 11 and controlling the orientation and the particle size of the magnetic free layer 12 may be disposed as a buffer layer between the lower electrode layer 11 and the magnetic free layer 12. The buffer layer is preferably made of, e.g., a film of Ta and NICr or a film of Ta and Ru. A film thickness of the buffer layer is preferably about 2 nm to 6 nm, for example.

The magnetic free layer 12 is a layer in which the direction of magnetization is changed depending on an external magnetic field or a spin polarized electron.

When a material having an easy magnetization axis in the direction of the film surface is to be selected, the magnetic free layer 12 is constituted as a film made of, e.g., CoFe, CoFeB, CoFeSi, CoMnGe, CoMnSi or CoMnAl and having a thickness of about 1 nm to 10 nm, for example. A soft magnetic film made of, e.g., NiFe and having a thickness of about 1 nm to 9 nm, for example, may be added as a magnetostriction adjustment layer to the above-mentioned film.

When a material having an easy magnetization axis in the direction normal to the film surface is to be selected, the magnetic free layer 12 is made of, e.g., Co, a Co/non-magnetic layer stacked film, a CoCr-based alloy, a Co multilayer film, a CoCrPt-based alloy, a FePt-based alloy, a SmCo-based alloy containing a rare earth, a TbFeCo alloy, or an Heustler alloy.

A highly spin polarized material may be inserted between the multilayer structure of the magnetic free layer 12 and the non-magnetic spacer layer 13. A high magnetoresistance ratio can be obtained with the insertion of the highly spin polarized material.

The highly spin polarized material is, e.g., a CoFe alloy or a CoFeB alloy. A thickness of a film of the CoFe alloy or the CoFeB alloy is preferably 0.2 nm to 1 nm.

An induced magnetic anisotropy may be introduced to the magnetic free layer 12 by applying a constant magnetic field in the direction perpendicular to its film surface when the magnetic free layer 12 is formed.

The non-magnetic spacer layer 13 is a layer for making the magnetization of the magnetic free layer 12 and the magnetization of the magnetic pinned layer 14 interact to develop the magnetoresistive effect.

The non-magnetic spacer layer 13 is, e.g., a layer made of an insulator or a semiconductor, or a layer including a conducting point, which is formed by a conductor, in an insulator.

When an insulator is employed as the material of the non-magnetic spacer layer 13, the insulator is, e.g., Al₂O₃ or magnesium oxide (MgO). Preferably, the lattice constant of the non-magnetic spacer layer 13 and the lattice constant of the magnetic pinned layer 14 are as close as possible to each other, and the lattice constant of the non-magnetic spacer layer 13 and the lattice constant of the magnetic free layer 12 are as close as possible to each other. As a result, a coherent tunneling effect is developed through the non-magnetic spacer layer 13, and a higher magnetoresistance ratio can be obtained. A film thickness of the insulator is preferably about 0.5 nm to 2.0 nm.

When a semiconductor is employed as the material of the non-magnetic spacer layer 13, the non-magnetic spacer layer 13 preferably has a structure in which a first non-magnetic metal layer, a semiconductor oxide layer, and a second non-magnetic metal layer are successively stacked from the side close to the magnetic free layer 12. A material of the first non-magnetic metal layer is, e.g., Cu or Zn. A film thickness of the first non-magnetic metal layer is preferably about 0.1 nm to 1.2 nm. A material of the semiconductor oxide layer is, e.g., zinc oxide (ZnO), indium oxide (In₂O₃), tin oxide (SnO₂), Indium Tin Oxide (ITO), or gallium oxide (GaOₓ or Ga₂Oₓ). A film thickness of the semiconductor oxide layer is preferably about 1.0 nm to 4.0 nm. A material of the second non-magnetic metal layer is, e.g., Zn, an alloy of Zn and Ga, a film of Zn and GaO, Cu, or an alloy of Cu and Ga. A film thickness of the second non-magnetic metal layer is preferably about 0.1 nm to 1.2 nm.

When the layer including the conducting point, which is formed by a conductor, in an insulator is employed as the non-magnetic spacer layer 13, the non-magnetic spacer layer 13 preferably has a structure that the conducting point formed by a conductor, such as CoFe, CoFeB, CoFeSi, CoMnGe, CoMnSi, CoMnAl, Fe, Co, Au, Cu, Al or Mg, is contained in an insulator made of Al₂O₃ or magnesium oxide (MgO). A film thickness of the insulator or the conductor is preferably about 0.5 nm to 2.0 nm.

The magnetic pinned layer 14 is a layer that is constituted by a ferromagnetic layer and an antiferromagnetic layer, and that is given with unidirectional magnetic anisotropy through exchange coupling. In a preferred form, the magnetic pinned layer 14 constitutes the so-called synthetic pinned layer having a structure in which an inner layer, a non-magnetic intermediate layer, an outer layer, and an antiferromagnetic layer (all not illustrated) are successively stacked from the side close to the non-magnetic spacer layer 13.

Each of the inner layer and the outer layer is constituted in the form including a ferromagnetic layer that is made of a ferromagnetic material containing Co or Fe, for example. The inner layer and the outer layer are coupled in an antiferromagnetic fashion and are pinned such that their magnetization directions are reversed to each other.

Preferably, each of the inner layer and the outer layer is made of, e.g., a CoFe alloy, or it has a multilayer structure made of CoFe alloys having different compositions or a multilayer structure made of a CoFeB alloy and a CoFe alloy. Preferably, a film thickness of the inner layer is about 1 to 10 nm, and a film thickness of the outer layer is about 1 to 7 nm. The inner layer may contain a Heusler alloy.

The non-magnetic intermediate layer is made of a non-magnetic material that contains, for example, at least one selected from a group consisting of Ru, Rh, Ir, Re, Cr, Zr and Cu. A film thickness of the non-magnetic intermediate layer is about 0.35 nm to 1.0 nm, for example. The non-magnetic intermediate layer is disposed to pin magnetization of the inner layer and magnetization of the outer layer such that directions of both the magnetizations are reversed to each other. The expression “directions of the magnetizations are reversed to each other” is not to be construed in a limitative sense of narrowing the scope of the invention only to the case where the two magnetization directions are different by 180° from each other, and it is to be construed in a broader sense involving the case where the two magnetization directions are different by 180°±20° from each other.

The antiferromagnetic layer is made of an antiferromagnetic material containing, for example, not only at least one element selected from a group consisting of Pt, Ru, Rh, Pd, Ni, Cu, Ir, Cr and Fe, but also Mn. The content of Mn is preferably 35 at % to 95 at %. The antiferromagnetic material is classified into a non-thermally treated antiferromagnetic material that exhibits anti-ferromagnetism without being thermally treated, and that induces exchange coupling with respect to a ferromagnetic material, and a thermally treated antiferromagnetic material that exhibits anti-ferromagnetism after being thermally treated. Any of those two types of ferromagnetic materials may be used in the present invention. The non-thermally treated antiferromagnetic material is, e.g., RuRhMn, FeMn, or IrMn. The thermally treated antiferromagnetic material is, e.g., PtMn, NiMn, or PtRhMn. Usually, even when the non-thermally treated antiferromagnetic material is used, it is also thermally treated to make the direction of exchange coupling uniform. A film thickness of the antiferromagnetic layer is preferably about 4 nm to 30 nm.

A layer with the function of protecting the magnetic pinned layer 14 from oxidation, etching, and so on may be disposed as a cap layer between the magnetic pinned layer 14 and the upper electrode layer 15. The cap layer is preferably, e.g., a Ru film, a Ta film, or a multilayer film of Ru and Ta, and a film thickness of the cap layer is preferably about 2 nm to 10 nm.

After forming the magnetic pinned layer 14, annealing is performed to pin the magnetization of the magnetic pinned layer 14. The annealing is preferably performed at pressure of 1.0×10⁻³ Pa or less and at temperature of 250° C. to 300° C. for a time of 1 hour to 5 hours under application of a magnetic field of 3 kOe to 10 kOe.

After the annealing, a first stage of photoresist patterning and ion beam etching is performed for patterning of the magnetic free layer 12, the non-magnetic spacer layer 13, and the magnetic pinned layer 14 into the desired shapes. The insulator 16 is then disposed by, e.g., the sputtering method or the IBD method in regions where the above-mentioned layers have been removed. The insulator 16 is preferably made of a material that is a non-magnetic material, and that is superior in insulation performance and chemical stability, such as Al₂O₃ or SiO₂.

A final shape of the magnetic free layer 12 is specified by the first stage of photoresist patterning and ion beam etching. Given that a minimum value of an area of the magnetic free layer 12 in a section perpendicular to the stacking direction is denoted by Sf, as illustrated in FIG. 2, a section of the magnetic free layer 12 perpendicular to the stacking direction has the same shape and the same area at any position in a film surface in the stacking direction. Thus, Sf has the same value regardless of the area being measured at what a position in the film surface in the stacking direction.

Next, a second stage of photoresist patterning and ion beam etching is performed for patterning of the magnetic pinned layer 14 into the desired shape. The insulator 17 is then disposed by, e.g., the sputtering method or the IBD method in a region where the magnetic pinned layer 14 has been removed. The insulator 17 may be made of the same material as or a different material from that of the insulator 16 insofar as the insulator 17 is made of a material that is a non-magnetic material, and that is superior in insulation performance and chemical stability.

In the second stage of ion beam etching, the ion beam etching is continued up to a position at which the non-magnetic spacer layer 13 is slightly removed, in order to completely remove a portion of the magnetic pinned layer 14, the portion being positioned outside a region protected by the second stage of photoresist patterning when viewed in a section perpendicular to the stacking direction. Because the main material of the non-magnetic spacer layer 13, such as MgO or Al₂O₃, has higher resistance against the ion beam etching than the main materials of the magnetic pinned layer 14 and the magnetic free layer 12, it is easy to stop the ion beam etching at the position at which the non-magnetic spacer layer 13 isslightly removed.

A final shape of the magnetic pinned layer 14 is specified by the second stage of photoresist patterning and ion beam etching. Assume that the minimum value of an area of the magnetic free layer 12 in the section perpendicular to the stacking direction is denoted by Sf, an area of the magnetic pinned layer 14 in a section perpendicular to the stacking direction is denoted by Sp, a minimum value of the area of the magnetic pinned layer 14 in a section perpendicular to the stacking direction is denoted by Spm, and an area of an interface at which the magnetic pinned layer 14 and the non-magnetic spacer layer 13 are in contact with each other is denoted by Spn. Moreover, assume that, as illustrated in FIG. 2, a minimum distance between a section of the magnetic pinned layer 14 perpendicular to the stacking direction, the section satisfying relation of Sf>2×Sp, and the interface at which the magnetic pinned layer 14 and the non-magnetic spacer layer 13 are in contact with each other is denoted by Lp.

Respective sections of the magnetic free layer 12 and the magnetic pinned layer 14 perpendicular to the stacking direction are not limited to particular shapes, but they preferably have a shape including no acute angles, such as a circular or elliptical shape.

In the magnetic element 1, Sf is specified to be larger than Spm, and more particularly Sf is specified to be larger than 2×Spm. Since Sf is larger than Spm, a current having been confined by the magnetic pinned layer 14 passes through an end portion of the magnetic free layer 12 in a smaller amount, and the amount of the current passing through an inner region of the magnetic free layer 12 except for the end portion thereof is increased. Moreover, since Sf is larger than 2×Spm, namely since Sf is sufficiently larger than Spm, the current having been confined by the magnetic pinned layer 14 passes through the end portion of the magnetic free layer 12 in an even smaller amount, and the amount of the current passing through the inner region of the magnetic free layer 12 is further increased.

Moreover, Lp is preferably 2 nm or less. On that condition, the current having passed through a region of the magnetic pinned layer 14, the region satisfying the relation of Sf>2×Sp, passes through the non-magnetic spacer layer 13 and then flows into the magnetic free layer 12 without being diffused again in the magnetic pinned layer 14 up to a region corresponding to the area Sf. As a result, the amount of the current passing through the end portion of the magnetic free layer 12 is further reduced, and the amount of the current passing through the inner region of the magnetic free layer 12 is further increased.

In addition, in the magnetic element 1, Sf is specified to be larger than Spn. On that condition, the current is confined by a portion of the magnetic pinned layer 14, the portion being in contact with the non-magnetic spacer layer 13, and the effect of confining the current passing through the non-magnetic spacer layer 13 and flowing into the magnetic free layer 12 is increased. Thus, the current having been confined by the magnetic pinned layer 14 passes through the end portion of the magnetic free layer 12 in a smaller amount, and the amount of the current passing through the inner region of the magnetic free layer is increased.

A uniform external magnetic field is applied to the inner region of the magnetic free layer 12, and deterioration attributable to the processing is not caused there. This further contributes to reducing the amount of the current passing through the end portion of the magnetic free layer 12, and to increasing the amount of the current passing through the inner region of the magnetic free layer. As a result, uniform precession of magnetization is generated in the magnetic free layer 12, whereby the purity of an oscillation signal is improved and a higher oscillation output is realized.

After the second stage of photoresist patterning and ion beam etching, the upper electrode layer 15 is disposed. The upper electrode layer 15 is constituted as a film made of Ta, Cu, Au, AuCu, or Ru, or a film made of two or more selected from among those materials, each film being formed by the sputtering method or the IBD method, for example. A film thickness of the upper electrode layer 15 is preferably about 0.05 μm to 5 μm. In the magnetic element 1, the shape of the electrode layer is important for the purpose of reducing the transmission loss. In the first embodiment of the present invention, the upper electrode layer 15 is specified into the coplanar waveguide (CPW) shape, when looking at the magnetic element 1 from above, by photoresist patterning or ion beam etching, for example.

While the magnetic field supply mechanism 2 according to the first embodiment of the present invention is a magnetic field supply mechanism of the electromagnet type capable of controlling the magnitude and the direction of the applied magnetic field depending on a voltage or a current, the present invention is not limited to such an example. Similar advantageous effects can also be obtained even when the magnetic field supply mechanism 2 is constituted as a magnetic field supply mechanism in combination of the electromagnet type and the fixed magnet type that supplies only a certain magnetic field. Moreover, in the case of employing the magnetic element 1 only at a single frequency without utilizing variability of the frequency characteristics of the magnetic element 1, similar advantageous effects can be likewise obtained even when the magnetic field supply mechanism 2 is constituted as a magnetic field supply mechanism including only the fixed magnet type. If there is no need of taking into account a production cost, similar advantageous effects can be obtained even when the magnetic field supply mechanism 2 is constituted by installing an external device to be positioned near the magnetic pinned layer 14 of the magnetic element 1.

While, in the first embodiment of the present invention, the shapes of the magnetic free layer 12, the non-magnetic spacer layer 13, and the magnetic pinned layer 14 are specified through the two stages of photoresist patterning and ion beam etching, the present invention is not limited to such an example. Insofar as the relation that Sf is larger than Spm is satisfied, similar advantageous effects can be obtained even when the shapes of the magnetic free layer 12, the non-magnetic spacer layer 13, and the magnetic pinned layer 14 are specified through any one of the photoresist patterning and the ion beam etching, or by performing both the photoresist patterning and the ion beam etching three or more times.

Furthermore, insofar as the relation that Sf is larger than Spm is satisfied, a section of the magnetic pinned layer 14 perpendicular to the stacking direction may have the same shape and the same area when viewed at any position in a film surface in the stacking direction. Alternatively, insofar as the relation that Sf is larger than Spm is satisfied, the shape and the area of the section of the magnetic pinned layer 14 perpendicular to the stacking direction may be changed depending on the position in the film surface in the stacking direction.

As described above, the magnetic element 1 includes the magnetoresistive effect film 10 including the magnetic pinned layer 14 and the magnetic free layer 12 with the non-magnetic spacer layer 13 interposed therebetween, and the pair of electrodes (i.e., the lower electrode layer 11 and the upper electrode layer 15) arranged with the magnetoresistive effect film 10 interposed therebetween in the stacking direction. Given that the minimum value of the area of the magnetic free layer 12 in the section perpendicular to the stacking direction is denoted by Sf, and that the minimum value of the area of the magnetic pinned layer 14 in the section perpendicular to the stacking direction is denoted by Spm, the relation of Sf>Spm is satisfied. On that condition, since the area of the magnetic free layer 12 in the section perpendicular to the stacking direction is larger than the minimum value of the area of the magnetic pinned layer 14 in the section perpendicular to the stacking direction, the current having been confined by the magnetic pinned layer 14 passes through the end portion of the magnetic free layer 12 in a smaller amount, and the amount of the current passing through the inner region of the magnetic free layer is increased. A uniform external magnetic field is applied to the inner region of the magnetic free layer 12, and deterioration attributable to the processing is not caused there. As a result, uniform precession of magnetization is generated in the magnetic free layer 12, whereby the purity of an oscillation signal is improved and a higher oscillation output is realized.

Furthermore, in the magnetic element 1, the relation of Sf>2×Spm is satisfied. On that condition, since the area of the magnetic free layer 12 in the section perpendicular to the stacking direction is sufficiently larger than the minimum value of the area of the magnetic pinned layer 14 in the section perpendicular to the stacking direction, the current having been confined by the magnetic pinned layer 14 passes through the end portion of the magnetic free layer 12 in a smaller amount, and the amount of the current passing through the inner region of the magnetic free layer is further increased. A uniform external magnetic field is applied to the inner region of the magnetic free layer 12, and deterioration attributable to the processing is not caused there. As a result, uniform precession of magnetization is generated in the magnetic free layer 12, whereby the purity of an oscillation signal is improved and a higher oscillation output is realized.

Moreover, in the magnetic element 1, given that when the area of the magnetic pinned layer 14 in the section perpendicular to the stacking direction is denoted by Sp, the minimum distance between a section of the magnetic pinned layer 14 perpendicular to the stacking direction, the section satisfying the relation of Sf>2×Sp, and the interface at which the magnetic pinned layer 14 and the non-magnetic spacer layer 13 are in contact with each other is denoted by Lp, the relation of Lp≦2 [nm] is satisfied. On that condition, even when an area of the interface at which the magnetic pinned layer 14 and the non-magnetic spacer layer 13 are in contact with each other is larger than the minimum value of the area of the magnetic pinned layer 14 in the section perpendicular to the stacking direction, the current having been confined by a region of the magnetic pinned layer 14, the region satisfying the relation of Sf>2×Sp, passes through the non-magnetic spacer layer 13 and then flows into the magnetic free layer 12 without being diffused again in the magnetic pinned layer 14 up to a region corresponding to the area Sf. As a result, uniform precession of magnetization is generated in the magnetic free layer 12, whereby the purity of an oscillation signal is improved and a higher oscillation output is realized.

In addition, in the magnetic element 1, given that the area of the interface at which the magnetic pinned layer 14 and the non-magnetic spacer layer 13 are in contact with each other is denoted by Spn, the relation of Sf>Spn is satisfied. On that condition, since the current is confined by a portion of the magnetic pinned layer 14, the portion being in contact with the non-magnetic spacer layer 13, the effect of confining the current passing through the non-magnetic spacer layer 13 and flowing into the magnetic free layer 12 is increased. Thus, the current having been confined by the magnetic pinned layer 14 passes through the end portion of the magnetic free layer 12 in a smaller amount, and the amount of the current passing through the inner region of the magnetic free layer 12 is increased. As a result, uniform precession of magnetization is generated in the magnetic free layer 12, whereby the purity of an oscillation signal is improved and a higher oscillation output is realized.

### Second Embodiment

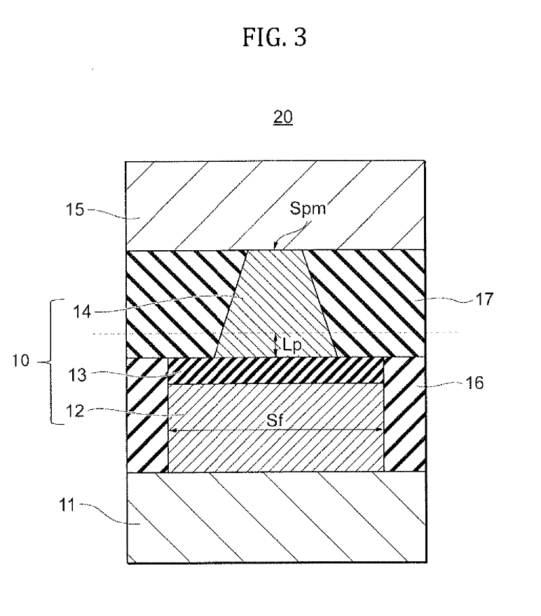

FIG. 3 is a sectional view illustrating a detailed multilayer structure of a magnetic element 20 according to a second embodiment of the present invention. The magnetic element 20 is different from the magnetic element 1 according to the first embodiment, illustrated in FIG. 2, in that, during the second stage of ion beam etching, the ion beam etching is stopped without removing the non-magnetic spacer layer 13 as soon as the portion of the magnetic pinned layer 14 positioned outside the region protected by the second stage of photoresist patterning, when viewed in a section perpendicular to the stacking direction, is completely removed. Other points are similar to those in the magnetic element 1 according to the first embodiment. The advantageous effect of realizing a higher oscillation output and the principle of realization of the effect are also similar to those in the first embodiment.

### Third Embodiment

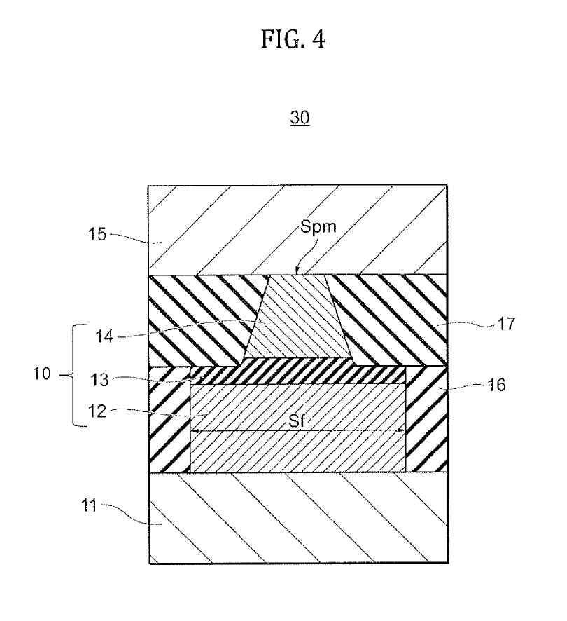

FIG. 4 is a sectional view illustrating a detailed multilayer structure of a magnetic element 30 according to a third embodiment of the present invention. The magnetic element 30 is different from the magnetic element 1 according to the first embodiment, illustrated in FIG. 2, in that the relation of Sf>2×Spn is satisfied and Lp=0 [nm] is held. Other points are similar to those in the magnetic element 1 according to the first embodiment.

In the magnetic element 30, since the area of the magnetic free layer 12 in the section perpendicular to the stacking direction is sufficiently larger than a portion of the magnetic pinned layer 14, the portion being in contact with the non-magnetic spacer layer 13 and serving to confine the current, the current having been confined by the magnetic pinned layer 14 passes through the end portion of the magnetic free layer 12 in a smaller amount, and the current passes through the inner region of the magnetic free layer 12 in a larger amount than those amounts obtained in the first embodiment. As a result, more uniform precession of magnetization is generated in the magnetic free layer, whereby the purity of an oscillation signal is improved and a higher oscillation output is realized.

### Fourth Embodiment

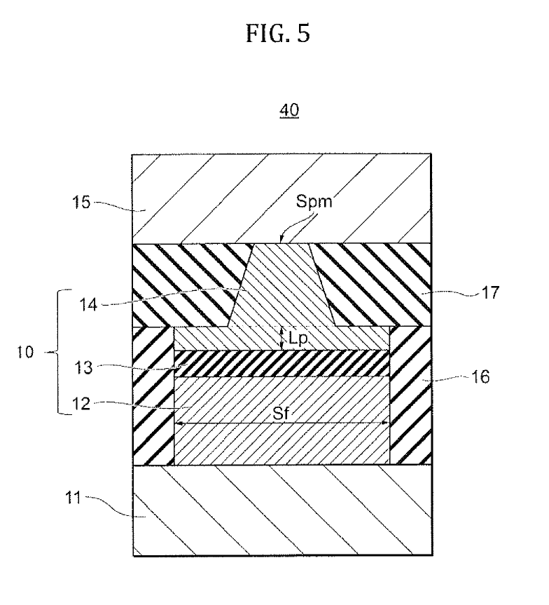

FIG. 5 is a sectional view illustrating a detailed multilayer structure of a magnetic element 40 according to a fourth embodiment of the present invention. The magnetic element 40 is different from the magnetic element 1 according to the first embodiment, illustrated in FIG. 2, in that, during the second stage of ion beam etching, the ion beam etching is stopped at a time at which the magnetic pinned layer 14 slightly remains, without completely removing the portion of the magnetic pinned layer 14 positioned outside the region protected by the second stage of photoresist patterning when viewed in the section perpendicular to the stacking direction. A thickness of the magnetic pinned layer 14 remaining outside the protected region is equal to Lp. Other points are similar to those in the magnetic element 1 according to the first embodiment. In the magnetic element 40, Lp is preferably 2 nm or less as in the magnetic element 1. As a result, the current having passed through a region of the magnetic pinned layer 14, the region satisfying the relation of Sf>2×Sp, passes through the non-magnetic spacer layer 13 and then flows into the magnetic free layer 12 without being diffused again in the magnetic pinned layer 14 up to a region corresponding to the area Sf. As a result, the amount of the current passing through the end portion of the magnetic free layer 12 is further reduced, and the amount of the current passing through the inner region of the magnetic free layer 12 is further increased. As a result, uniform precession of magnetization is generated in the magnetic free layer 12, whereby the purity of an oscillation signal is improved and a higher oscillation output is realized.

Moreover, an amount by which the current having been confined by a region of the magnetic pinned layer 14, the region satisfying the relation of Sf>2×Sp, is diffused again in the magnetic pinned layer 14 up to the region corresponding to the area Sf can be further reduced by additionally employing, during fabrication of the magnetic element 40, a process of, after stopping the second stage of photoresist patterning, performing ion etching with activation gas, such as represented by oxygen, nitrogen, or halogen, without removing a mask material that has been formed by the second stage of photoresist patterning, and denaturizing an outer remaining region of the magnetic pinned layer 14, the region having a thickness corresponding to Lp, to such an extent that electrical conductivity is lost in the outer remaining region.

### Fifth Embodiment

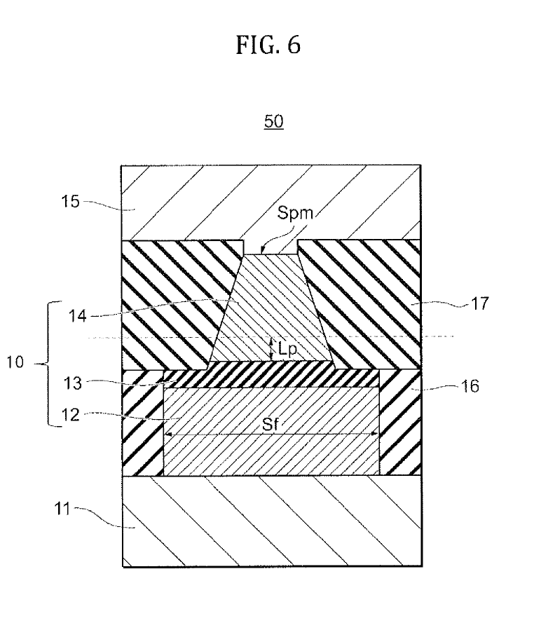

FIG. 6 is a sectional view illustrating a detailed multilayer structure of a magnetic element 50 according to a fifth embodiment of the present invention. The magnetic element 50 is different from the magnetic element 1 according to the first embodiment, illustrated in FIG. 2, in that a region of the upper electrode layer 15, the region being in contact with the magnetic pinned layer 14, is specified into a microscopic shape comparable to that of the magnetic pinned layer 14. Other points are similar to those in the magnetic element 1 according to the first embodiment. The advantageous effect of realizing a higher oscillation output and the principle of realization of the effect are also similar to those in the first embodiment.

### Sixth Embodiment

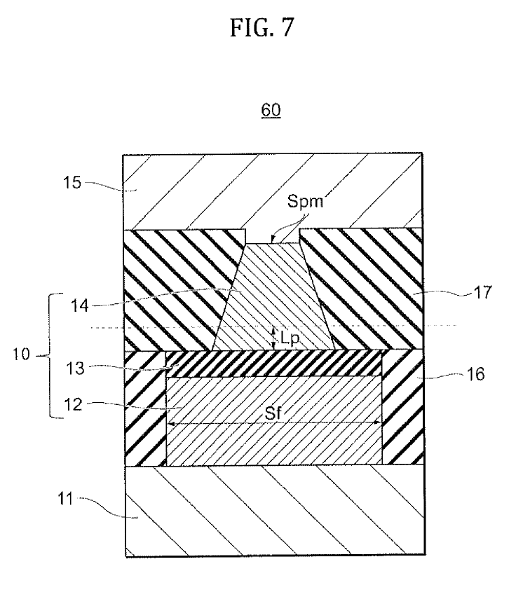

FIG. 7 is a sectional view illustrating a detailed multilayer structure of a magnetic element 60 according to a sixth embodiment of the present invention. The magnetic element 60 is different from the magnetic element 20 according to the second embodiment, illustrated in FIG. 3, in that a region of the upper electrode layer 15, the region being in contact with the magnetic pinned layer 14, is specified into a microscopic shape comparable to that of the magnetic pinned layer 14. Other points are similar to those in the magnetic element 20 according to the second embodiment. The advantageous effect of realizing a higher oscillation output and the principle of realization of the effect are also similar to those in the second embodiment.

### Seventh Embodiment

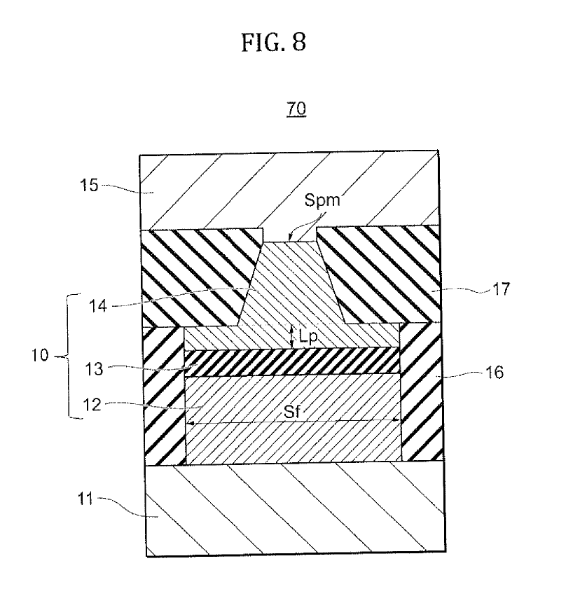

FIG. 8 is a sectional view illustrating a detailed multilayer structure of a magnetic element 70 according to a seventh embodiment of the present invention. The magnetic element 70 is different from the magnetic element 40 according to the fourth embodiment, illustrated in FIG. 5, in that a region of the upper electrode layer 15, the region being in contact with the magnetic pinned layer 14, is specified into a microscopic shape comparable to that of the magnetic pinned layer 14. Other points are similar to those in the magnetic element 40 according to the fourth embodiment. The advantageous effect of realizing a higher oscillation output and the principle of realization of the effect are also similar to those in the fourth embodiment.

### Eighth Embodiment

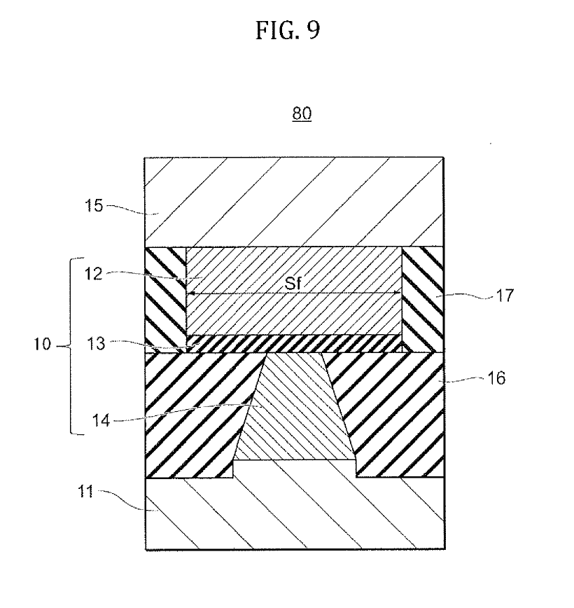

FIG. 9 is a sectional view illustrating a detailed multilayer structure of a magnetic element 80 according to an eighth embodiment of the present invention. The magnetic element 80 is different from the magnetic element 20 according to the second embodiment, illustrated in FIG. 3, in that the lower electrode layer 11, the magnetic pinned layer 14, the non-magnetic spacer layer 13, the magnetic free layer 12, and the upper electrode layer 15 are successively disposed in the mentioned order, that an upper end portion of the lower electrode layer 11 is processed into the same shape as the magnetic pinned layer 14 at a position in contact with the magnetic pinned layer 14, and that the relation of Sf>2×Spn is satisfied and Lp=0 [nm] is held. Other points are similar to those in the magnetic element 20 according to the second embodiment. After forming the magnetic pinned layer 14, the first stage of photoresist patterning and ion beam etching is performed to specify the respective shapes of the magnetic pinned layer 14 and the upper end portion of the lower electrode layer 11. In the first stage of ion beam etching, the ion beam etching is continued up to a position at which the lower electrode layer 11 is slightly removed, in order to completely remove a portion of the magnetic pinned layer 14, the portion being positioned outside a region protected by the first stage of photoresist patterning when viewed in a section perpendicular to the stacking direction. Next, after forming the non-magnetic spacer layer 13 and the magnetic free layer 12, the second stage of photoresist patterning and ion beam etching is performed to specify the respective shapes of the non-magnetic spacer layer 13 and the magnetic free layer 12. Other points are similar to those in the magnetic element 20 according to the second embodiment. The advantageous effect of realizing a higher oscillation output and the principle of realization of the effect are similar to those in the magnetic element 30 according to the third embodiment.

### Ninth Embodiment

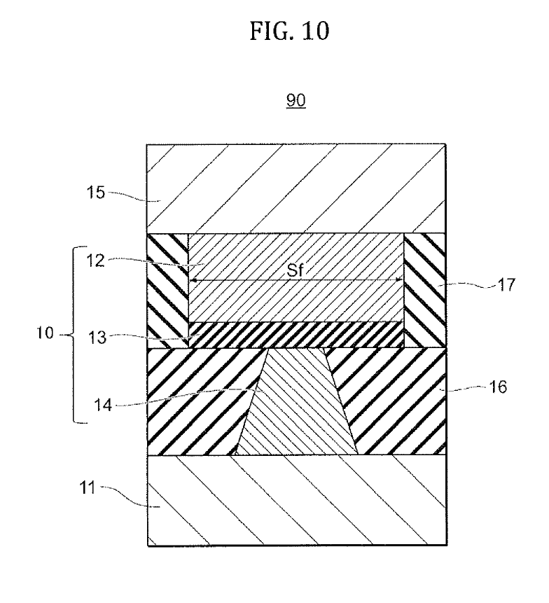

FIG. 10 is a sectional view illustrating a detailed multilayer structure of a magnetic element 90 according to a ninth embodiment of the present invention. The magnetic element 90 is different from the magnetic element 80 according to the eighth embodiment, illustrated in FIG. 9, in that, during the first stage of ion beam etching, the ion beam etching is stopped without removing the lower electrode layer 11 as soon as the portion of the magnetic pinned layer 14 positioned outside the region protected by the first stage of photoresist patterning, when viewed in the section perpendicular to the stacking direction, is completely removed. Other points are similar to those in the magnetic element 80 according to the eighth embodiment. The advantageous effect of realizing a higher oscillation output and the principle of realization of the effect are also similar to those in the eighth embodiment.

### Tenth Embodiment

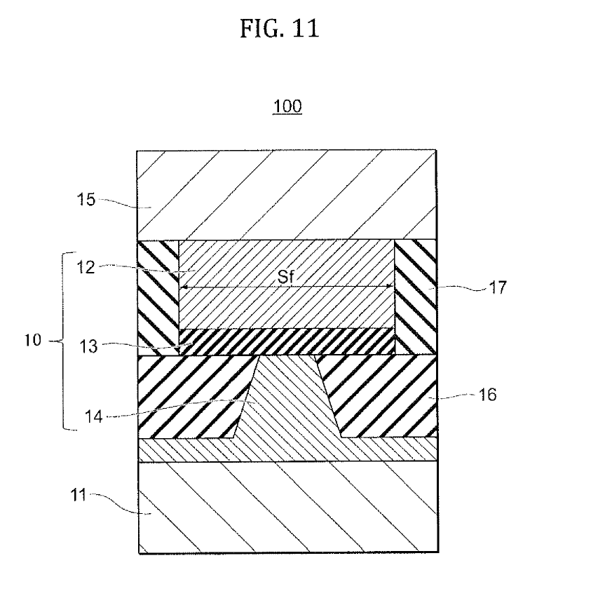

FIG. 11 is a sectional view illustrating a detailed multilayer structure of a magnetic element 100 according to a tenth embodiment of the present invention. The magnetic element 100 is different from the magnetic element 80 according to the eighth embodiment, illustrated in FIG. 9, in that, during the first stage of ion beam etching, the ion beam etching is stopped at a time at which the portion of the magnetic pinned layer 14 positioned outside the region protected by the first stage of photoresist patterning, when viewed in the section perpendicular to the stacking direction, slightly remains, without completely removing the relevant portion of the magnetic pinned layer 14. There is no significant limitation on an amount of the magnetic pinned layer 14 to be etched. However, if a film thickness of the remaining magnetic pinned layer 14 is too large, a current would flow into the non-magnetic spacer layer 13 through the insulator 16, and the current confining effect developed at an interface region of the magnetic pinned layer 14 in contact with the non-magnetic spacer layer 13 would reduce. Accordingly, the amount of the magnetic pinned layer 14 to be etched is preferably 2 nm or more. Other points are similar to those in the magnetic element 80 according to the eighth embodiment. The advantageous effect of realizing a higher oscillation output and the principle of realization of the effect are also similar to those in the eighth embodiment.

### EXAMPLES

The embodiments of the present invention will be described in more detail below in connection with Examples, but the present invention is not limited to the following Examples.

### Example 1

The magnetic element 30 described above in the third embodiment of the present invention was fabricated. More specifically, a film of Cu (90 nm) was formed, as the lower electrode layer 11, by the sputtering method, on a silicon substrate, which had an outer diameter of 6 inches and a thickness of 2 mm, and which included a thermally-oxidized film (1 μm) previously formed on a substrate surface. The lower electrode layer 11 was then patterned into the CPW shape by photoresist patterning and ion beam etching.

Next, the buffer layer, the magnetic free layer 12, the non-magnetic spacer layer 13, the magnetic pinned layer 14, and the cap layer were successively formed in the mentioned order by the sputtering method. The buffer layer was made of Ta (1 nm)/Ru (1 nm), the magnetic free layer 12 was made of Co30Fe70 (2 nm), and the non-magnetic spacer layer 13 was made of MgO (1 nm). The magnetic pinned layer 14 was made of Co70Fe30 (3 nm)/Ru (0.8 nm)/Co65Fe35 (3.5 nm)/IrMn (7 urn), and the cap layer was made of Ru (1 nm)/Ta (2 nm)/Ru (2 nm). A numeral in the parenthesis represents the film thickness of each layer. After forming those layers, annealing was performed in a vacuum magnetic field to pin the magnetization of the magnetic pinned layer. During the annealing, the pressure was set to 5×10⁻⁴ Pa, the applied magnetic field was set to 10 kOe in the direction parallel to the film surface, the temperature was set to 250 degrees, and the processing time was set to 3 hours.

Next, the first stage of photoresist patterning and ion beam etching was performed for patterning of the individual layers from the cap layer to the buffer layer into a square shape of 245 nm×245 nm when viewed from above. The insulator 16 was then formed by the IBD method and the lift-off method. The insulator 16 was made of Al₂O₃ (film thickness of 12 nm).

Next, the second stage of photoresist patterning and ion beam etching was performed for patterning of the cap layer, the magnetic pinned layer 14, and an upper portion of the non-magnetic spacer layer 13 into a square shape of 173 nm×173 nm when viewed from above. With the second stage of ion beam etching, the insulator 16 was etched up to a position indicated in FIG. 4. The insulator 17 was then formed by the IBD method and the lift-off method. The insulator 17 was made of Al₂O₃ (film thickness of 19.5 nm).

Next, the upper electrode layer 15 was formed by the photoresist patterning, the sputtering method, and the lift-off method. The upper electrode layer 15 was made of AuCu (film thickness of 200 nm).

As a result of the above-described process, the magnetic element 30 was obtained with Spm=Spn=29929 [nm²], Sf=60025 [nm²], and Lp=0 [nm].

As the magnetic field supply mechanism 2, an external device was installed near the magnetic element 30.

For the magnetic element 30 fabricated by the above-described process, an oscillation output was measured while an optimum current amount and an optimum direction of the applied magnetic field (at which the oscillation output was maximized) were selected by employing the magnetic field supply mechanism 2.

An oscillation phenomenon will be described in brief below. When a DC current is supplied to the magnetic element 30, an electron subjected to spin polarization by the magnetic pinned layer 14 is caused to flow into the magnetic free layer 12. Accordingly, spin torque is transferred and precession of magnetization is induced in the magnetic free layer 12, whereby the magnetization in the magnetic free layer 12 is going to be reversed. In the case of applying an external magnetic field in a direction in which torque is generated opposite to the direction of the reversal of the magnetization, large precession of the magnetization is generated in the magnetic free layer 12 when those two reversing torques are brought into the condition of being close to each other, and a high-frequency signal at a frequency corresponding to the period of the precession of the magnetization is output. Such a phenomenon is called the self-excited oscillation with spin injection.

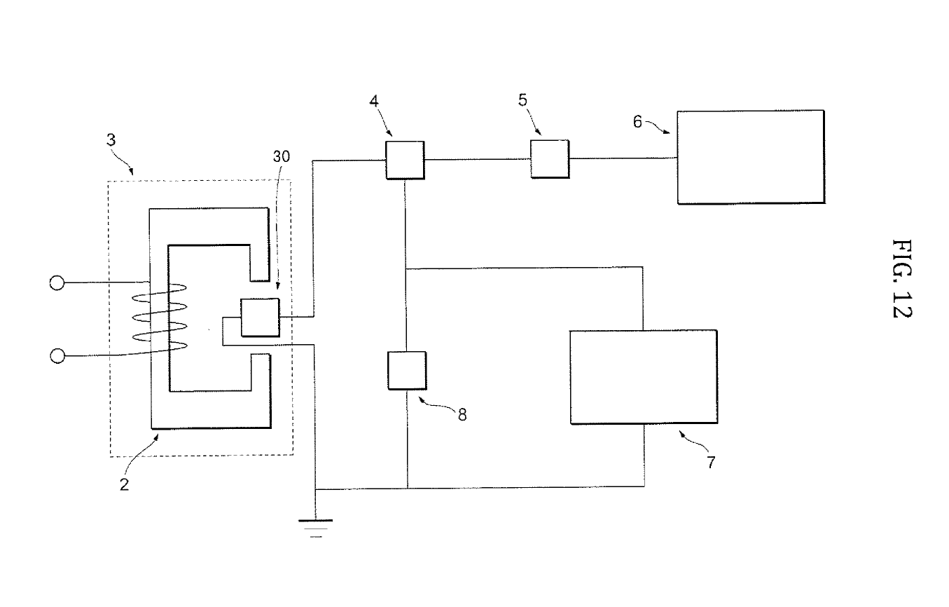

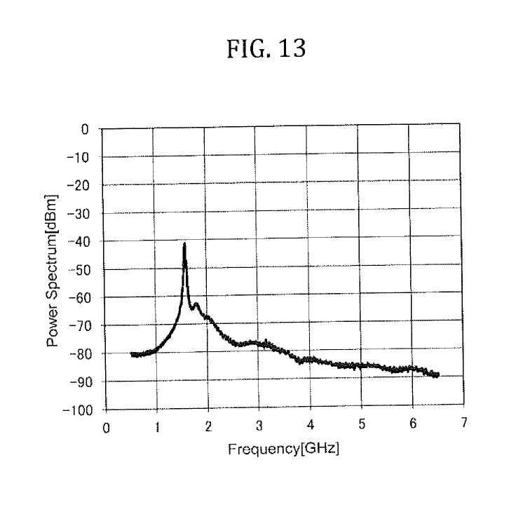

FIG. 12 is a block diagram of a device for measuring the oscillation output. The magnetic high frequency element 3 is constituted by the magnetic element 30 and the magnetic field supply mechanism 2. A Bias-Tee 4 separates an AC signal and a DC signal. A power amplifier 5 amplifies the AC signal having been separated by the Bias-Tee 4. A spectrum analyzer 6 measures an output of a high-frequency signal having been amplified by the power amplifier 5. A source meter 7 applies a current to the magnetic element 30. A diode 8 is connected to prevent breakdown of the magnetic element 30.

The current applied to the magnetic element 30 from the source meter 7 was set to 3 [mA] in consideration of the breakdown voltage of the magnetic element. The oscillation output was measured with the RBW (Resolution Band Width) of the spectrum analyzer 6 set to 3 [MHz]. FIG. 12 depicts the measurement result of a frequency and a power spectrum. A maximum peak of the power spectrum was −41.1 [dBm]. Table 1 represents a result obtained by calculating an oscillation output P [nW] from the above-mentioned result in consideration of the RBW and the half bandwidth. The oscillation output was 110 [nW].

TABLE 1

| | Sf | Spm | Spn | | Lp | P |
|---|---|---|---|---|---|---|
| | [nm²] | [nm²] | [nm²] | Sf/Spm | [nm] | [nW] |
| Example 1 | 60025 | 29929 | 29929 | 2.0 | 0 | 110 |
| Example 2 | 40000 | 19881 | 191881 | 2.0 | 0 | 180 |
| Example 3 | 20164 | 10000 | 10000 | 2.0 | 0 | 300 |
| Example 4 | 80089 | 40000 | 40000 | 2.0 | 0 | 80 |
| Example 5 | 48400 | 29929 | 29929 | 1.6 | 0 | 70 |
| Example 6 | 67600 | 29929 | 29929 | 2.3 | 0 | 110 |
| Example 7 | 78400 | 29929 | 29929 | 2.6 | 0 | 110 |
| Example 8 | 16129 | 10000 | 10000 | 1.6 | 0 | 190 |
| Example 9 | 22250 | 10000 | 10000 | 2.3 | 0 | 300 |
| Example 10 | 26244 | 10000 | 10000 | 2.6 | 0 | 300 |
| Example 11 | 60025 | 29929 | 60025 | 2.0 | 1 | 110 |
| Example 12 | 60025 | 29929 | 60025 | 2.0 | 2 | 110 |
| Example 13 | 60025 | 29929 | 60025 | 2.0 | 4 | 90 |
| Example 14 | 60025 | 29929 | 60025 | 2.0 | 7 | 50 |
| Example 15 | 60025 | 29929 | 60025 | 2.0 | 12 | 20 |
| Example 16 | 20164 | 10000 | 20164 | 2.0 | 1 | 300 |
| Example 17 | 20164 | 10000 | 20164 | 2.0 | 2 | 300 |
| Example 18 | 20164 | 10000 | 20164 | 2.0 | 4 | 245 |
| Example 19 | 20164 | 10000 | 20164 | 2.0 | 7 | 135 |
| Example 20 | 20164 | 10000 | 20164 | 2.0 | 12 | 40 |
| Comparative | 29929 | 29929 | 29929 | 1.0 | — | 20 |
| Example 1 | | | | | | |
| Comparative | 10000 | 10000 | 10000 | 1.0 | — | 10 |
| Example 2 | | | | | | |
| Comparative | 60025 | 60025 | 60025 | 1.0 | — | 15 |
| Example 3 | | | | | | |
| Comparative | 20164 | 20164 | 20164 | 1.0 | — | 30 |
| Example 4 | | | | | | |
| Comparative | 10000 | 20164 | 20164 | 0.5 | — | 10 |
| Example 5 | | | | | | |

### Examples 2 to 10

The magnetic element 30 described above in the third embodiment of the present invention was fabricated as each of Examples 2, 3, 4, 5, 6, 7, 8, 9 and 10. In Examples 2 to 10, the magnetic elements had the same structure as that in Example 1 except that Sf, Spm and Spn were set to values listed in Table 1. On each of the fabricated magnetic elements, the oscillation output was measured in the same manner as that in Example 1. Table 1 lists the respective values of Sf, Spm, Spn and Lp, and the results of the oscillation outputs in Examples 2 to 10.

### Examples 11 to 20

The magnetic element 40 described above in the fourth embodiment of the present invention was fabricated as each of Examples 11, 12, 13, 14, 15, 16, 17, 18, 19 and 20. In Examples 11 to 20, the magnetic elements had the same structure as that in Example 1 except that the magnetic pinned layer 14 remained at the thickness Lp in the above-described outer region of the magnetic pinned layer 14, and that Sf, Spm, Spn and Lp were set to values listed in Table 1. On each of the fabricated magnetic elements, the oscillation output was measured in the same manner as that in Example 1. Table 1 lists the respective values of Sf, Spm, Spn and Lp, and the results of the oscillation outputs in Examples 11 to 20.

### Comparative Examples 1 to 4

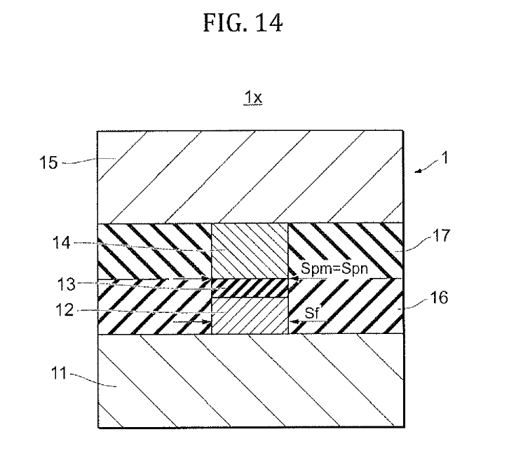

A magnetic element 1x, illustrated in FIG. 14, was fabricated as each of Comparative Examples 1, 2, 3 and 4. The magnetic elements 1x had the same structure as that in Example 1 except that the respective shapes and areas of the magnetic free layer 12 and the magnetic pinned layer 14 in sections perpendicular to the stacking direction were set equal to each other, and that Sf, Spm and Spn were set to values listed in Table 1. On each of the fabricated magnetic elements, the oscillation output was measured in the same manner as that in Example 1. Table 1 lists the respective values of Sf, Spm and Spn, and the results of the oscillation outputs in Comparative Examples 1 to 4.

### Comparative Example 5

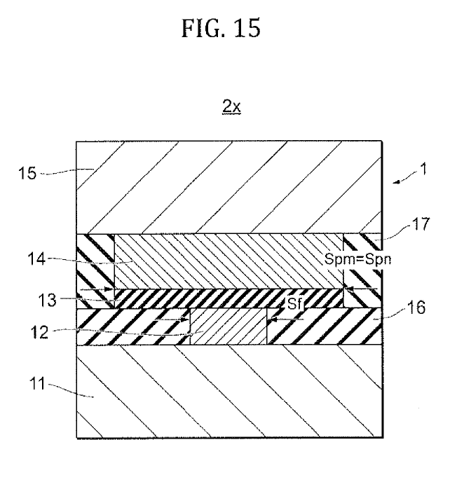

A magnetic element 2x, illustrated in FIG. 15, was fabricated. The magnetic element 2x had the same structure as that in Comparative Example 1 except that the area of the magnetic free layer 12 in a section perpendicular to the stacking direction is set smaller than an area of the magnetic pinned layer 14 in a section perpendicular to the stacking direction, and that Sf, Spm and Spn were set to values listed in Table 1. On the fabricated magnetic element, the oscillation output was measured in the same manner as that in Example 1. Table 1 lists the respective values of Sf, Spm and Spn, and the result of the oscillation output in Comparative Example 5.

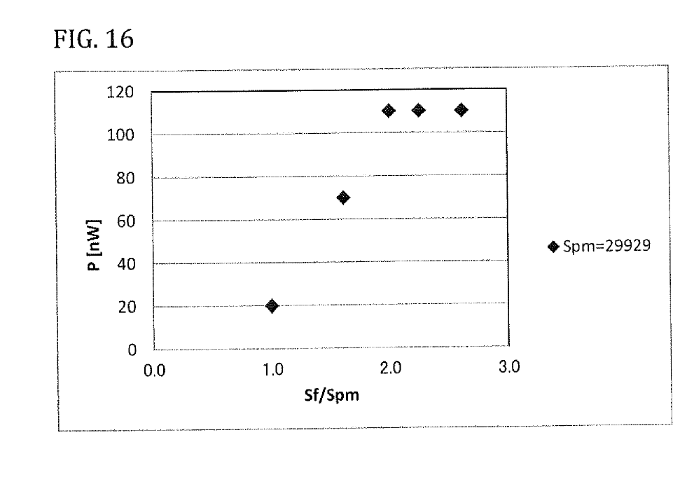

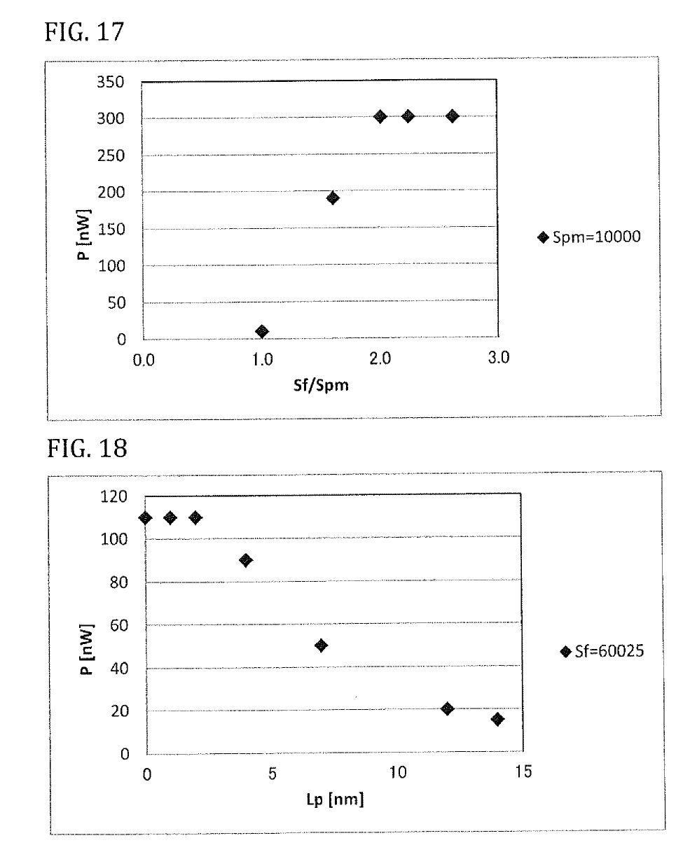

FIG. 16 is a graph representing relation between Sf/Spm and the oscillation output in Examples 1, 5, 6 and 7 and Comparative Example 1 each satisfying Spm=29929 [nm²]. FIG. 17 is a graph representing relation between Sf/Spm and the oscillation output in Examples 3, 8, 9 and 10 and Comparative Example 2 each satisfying Spm=10000 [nm²]. As seen from FIGS. 16 and 17, the oscillation output is increased in a range of Sf>Spm regardless of the value of Spm. It is thought that because the magnetic free layer 12 has an overall shape in a larger size than its partial region where a current having been confined by a region of the magnetic pinned layer 14 corresponding to Spm is injected after tunneling through the non-magnetic spacer layer 13 as a non-magnetic insulating layer, a current passing through the end portion of the magnetic free layer 12 is reduced, and a current passing through the inner region of the magnetic free layer 12 is increased. It is further thought that because a uniform external magnetic field is applied to the inner region of the magnetic free layer 12 and deterioration attributable to the processing is not caused there, uniform precession of magnetization is generated in the magnetic free layer 12, whereby the purity of an oscillation signal is improved and a higher oscillation output is realized.

Moreover, as seen from FIGS. 16 and 17, an improvement of the oscillation output is saturated in a range of Sf>2×Spm regardless of the value of Spm. It is thought that because the magnetic free layer 12 has an overall shape in a sufficiently larger size than its partial region where the current having been confined by the region of the magnetic pinned layer 14 corresponding to Spm is injected after tunneling through the non-magnetic spacer layer 13 as a non-magnetic insulating layer, a current passes only through the inner region of the magnetic free layer 12 without passing through the end portion of the magnetic free layer 12. It is further thought that because a uniform external magnetic field is applied to the inner region of the magnetic free layer 12 and deterioration attributable to the processing is not caused there, uniform precession of magnetization is generated in the magnetic free layer 12, whereby the purity of an oscillation signal is improved and a higher oscillation output is realized.

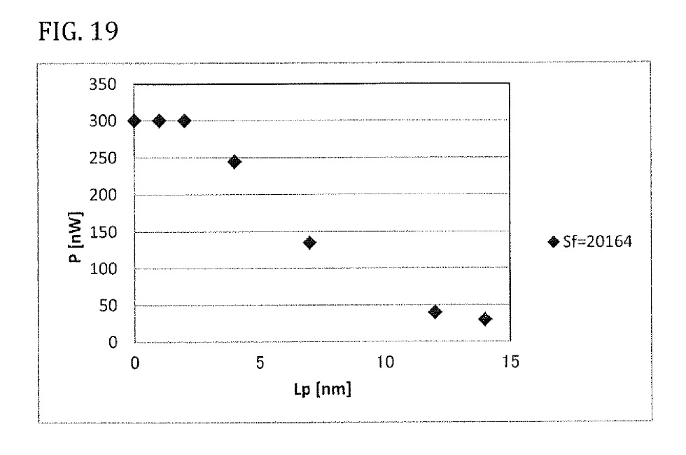

FIG. 18 is a graph representing relation between Lp and the oscillation output in Examples 1, 11, 12, 13, 14 and 15 each satisfying Sf>2×Spm and Sf=60025 [nm²]. FIG. 19 is a graph representing relation between Lp and the oscillation output in Examples 3, 16, 17, 18, 19 and 20 each satisfying Sf>2×Spm and Sf=20164 [nm²]. As seen from FIGS. 18 and 19, the oscillation output is increased regardless of the value of Sf as Lp reduces. It is thought that because a current having been confined by a region of the magnetic pinned layer 14, the region satisfying the relation of Sf>2×Sp, passes through the non-magnetic spacer layer 13 and then flows into the magnetic free layer 12 without being diffused again in the magnetic pinned layer 14 up to a region corresponding to the area Sf, the amount of the current passing through the end portion of the magnetic free layer 12 is reduced, and the amount of the current passing through the inner region of the magnetic free layer 12 is increased. Hence it is further thought that uniform precession of magnetization is generated, whereby the purity of an oscillation signal is improved and a higher oscillation output is realized.

Moreover, as seen from FIGS. 18 and 19, an improvement of the oscillation output is saturated regardless of the value of Sf in a range where Lp is 2 [nm] or less. It is thought that because, in the range where Lp is 2 [nm] or less, the current having been confined by a region of the magnetic pinned layer 14, the region satisfying the relation of Sf>2×Sp, passes through the non-magnetic spacer layer 13 and then flows into the magnetic free layer 12 without being diffused again in the magnetic pinned layer 14 up to the region corresponding to the area Sf, the current passes only through the inner region of the magnetic free layer 12 without passing through the end portion of the magnetic free layer 12. It is further thought that because a uniform external magnetic field is applied to the inner region of the magnetic free layer 12 and deterioration attributable to the processing is not caused there, uniform precession of magnetization is generated in the magnetic free layer 12, whereby the purity of an oscillation signal is improved and a higher oscillation output is realized.

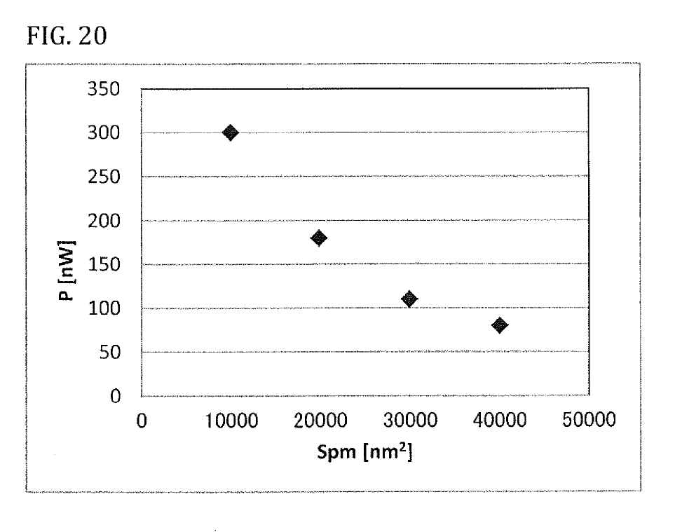

FIG. 20 is a graph representing relation between Spm and the oscillation output in Examples 1, 2, 3 and 4 each satisfying Lp=0 [nm] and Sf>2×Spm. As seen from the graph, the oscillation output is increased as Spm reduces. It is thought that because the inner region of the magnetic free layer where the current passes is reduced with a decrease of Spm, a state of the relevant region approaches a single magnetic domain and macroscopically uniform precession of magnetization is developed in the relevant region, whereby the purity of an oscillation signal is improved and a higher oscillation output is realized.

Regarding an output value required when the magnetic element is incorporated in a high frequency circuit, there is a threshold, i.e., a value of 0.1 [μW]=100 [nW], that is least necessary to amplify the output by the power amplifier. As seen from FIG. 20, in the range satisfying Sf>2×Spm at which the improvement of the oscillation output with an increase of Sf/Spm is saturated and satisfying Lp≦2 [nm] at which the improvement of the oscillation output is saturated with a decrease of Lp, Spm [nm²]<30000 [nm²] is a preferred condition when the magnetic element is to be incorporated in the high frequency circuit in practical use.

In Comparative Example 2, the oscillation output is reduced in spite of having Spm smaller than that in Comparative Example 1. The reason presumably resides in that because the size of the magnetic free layer 12 is reduced and a ratio of the area of an end portion of the magnetic free layer 12 to the volume of the magnetic free layer 12 is increased, the influence of degradation in the oscillation output, which is caused by the current passing through the end portion of the magnetic free layer, is more significant than the improvement of the oscillation output resulting from the formation of a single magnetic domain.

In Comparative Example 5, the oscillation output is reduced to a larger extent than that in Example 3 in which the region of the magnetic free layer 12 where the current passes is the same as in Comparative Example 5, i.e., 10000 [nm²]. This is presumably attributable to the influence of degradation in the oscillation output, which is caused by the current passing through the end portion of the magnetic free layer 12.

While the preferred examples of the present invention have been described above, the present invention can be modified into other forms than the above-described examples.

The magnetic element according to the present invention can be employed as a device, e.g., an oscillator, a detector, a mixer, or a filter, by utilizing high frequency characteristics of the magnetoresistive effect element. The magnetic element according to the present invention has a higher added value than an existing device, which is made of a semiconductor and which utilizes high frequency characteristics, in points of size reduction, impedance matching with a transfer circuit, and variability of frequency characteristics. In addition, since the oscillation output is increased in the present invention, the magnetic element according to the present invention can also be used instead of an existing device from the viewpoint of obtaining a higher oscillation output.

### REFERENCE SIGNS LIST

1, 20, 30, 40, 50, 60, 70, 80, 90, 100 magnetic elements
2 magnetic field supply mechanism
3 magnetic high frequency element
4 Bias-Tee
5 power amplifier
6 spectrum analyzer
7 source meter
8 diode
10 magnetoresistive effect film
11 lower electrode layer
12 magnetic free layer
13 non-magnetic spacer layer
14 magnetic pinned layer
15 upper electrode layer
16 insulator
17 insulator

What is claimed is:

1. A magnetic element comprising:
a magnetoresistive effect film including a magnetic pinned layer and a magnetic free layer with a non-magnetic spacer layer interposed therebetween; and
a pair of electrodes arranged with the magnetoresistive effect film interposed therebetween in a stacking direction of the magnetoresistive effect film,
wherein, given that a minimum value of an area of the magnetic free layer in a section perpendicular to the stacking direction is denoted by Sf and a minimum value of an area of the magnetic pinned layer in a section perpendicular to the stacking direction is denoted by Spm, relation of Sf>Spm is satisfied.

2. The magnetic element according to claim 1, wherein relation of Sf>2×Spm is satisfied.

3. The magnetic element according to claim 2, wherein, given that when an area of the magnetic pinned layer in a section perpendicular to the stacking direction is denoted by Sp, a minimum distance between a section of the magnetic pinned layer perpendicular to the stacking direction, the section satisfying relation of Sf>2×Sp, and an interface at which the magnetic pinned layer and the non-magnetic spacer layer are in contact with each other is denoted by Lp, relation of Lp≦2 [nm] is satisfied.

4. The magnetic element according to claim 1, wherein, given that an area of an interface at which the magnetic pinned layer and the non-magnetic spacer layer are in contact with each other is denoted by Spn, relation of Sf>Spn is satisfied.

5. The magnetic element according to claim 4, wherein relation of Sf>2×Spn is satisfied.

6. The magnetic element according to claim 1, wherein relation of Spm<30000 [nm²] is satisfied.

7. A magnetic high frequency element including the magnetic element according to claim 1, and a magnetic field supply mechanism that is installed near the magnetic free layer.
